(19) United States
(12) Patent Application Publication
(10) Pub. No.: US 2026/0164996 A1
(43) Pub. Date: Jun. 11, 2026

(54) Display Device

(71) Applicant: LG Display Co., Ltd., Seoul (KR)

(72) Inventors: Seong Il Kim, Paju-si (KR); Ji Su Han, Paju-si (KR); Byung Gwan Hyun, Paju-si (KR)

(21) Appl. No.: 19/327,559

(22) Filed: Sep. 12, 2025

(30) Foreign Application Priority Data
Dec. 11, 2024 (KR) 10-2024-0183506

(51) Int. Cl. H10K 59/80; H10K 59/40

(52) U.S. Cl. CPC H10K 59/873; H10K 59/8791; H10K 59/40

(57) ABSTRACT

A display device includes: a display panel and an optical device arranged in the display panel. The display panel includes: a substrate: a circuit layer arranged on the substrate; a light-emitting element layer arranged on the circuit layer; an encapsulation layer arranged on the light-emitting element layer; a color filter layer arranged on the encapsulation layer; and a cover layer arranged on the color filter layer, wherein the cover layer may include a first surface, which is in contact with the color filter layer, and a second surface, which is a surface opposite to the first surface. The roughness of the second surface may be changed by power applied to the cover layer.

### CROSS-REFERENCE TO RELATED APPLICATION

This application claims priority to and the benefit of Korean Patent Application No. 10-2024-0183506, filed on Dec. 11, 2024, the disclosure of which is incorporated herein by reference in its entirety.

### BACKGROUND

### Field

Embodiments relate to a display panel and a display device including the same.

### Discussion of Related Art

A display device is widely used as a display screen for a variety of electronic devices, such as a mobile communication terminal, an electronic notebook, an e-book, a portable multimedia player (PMP), a navigation system, an ultra-mobile PC (UMPC), a mobile phone, a tablet personal computer (PC), a watch phone, an electronic pad, a wearable device, a portable information device, a vehicle control display device, a television, a notebook computer, and a monitor.

The display device may include a separate cover glass that is exposed to the outside. Accordingly, there is a limitation in implementing a compact display device with reduced thickness.

In addition, in an outdoor environment where the intensity of external light, such as the sun, is high, the external light may be incident on the interior of a display panel through an opening, in which no black matrix is arranged, and then reflected by electrodes inside the display panel, thereby reducing display quality. For example, the opening may be formed to overlap light-emitting elements and serve as a path through which light is emitted from the light-emitting elements; and through the path, the external light may be emitted onto the electrodes inside the display panel and then reflected.

Accordingly, a user of the display device may apply an anti-reflection film onto the cover glass in response to external light. However, the anti-reflection film reduces display quality, such as resolution. In addition, the thickness of the display device may increase due to the anti-reflection film applied onto the cover glass.

Therefore, there is a demand for a display device incorporating the anti-reflection function.

### SUMMARY

Embodiments according to the present disclosure provide a display panel incorporating an anti-reflection function, and a display device including the display panel.

Embodiments according to the present disclosure provide a display panel, which has a reduced thickness due to a cover layer incorporating an anti-reflection function, and a display device including the display panel.

Objectives to be achieved by embodiments are not limited to the objectives described above, and objectives which are not described above will be clearly understood by those skilled in the art from the following descriptions.

A display device according to embodiments of the present disclosure includes: a display panel and an optical device arranged in the display panel, wherein the display panel includes: a substrate: a circuit layer arranged on the substrate; a light-emitting element layer arranged on the circuit layer; an encapsulation layer arranged on the light-emitting element layer; a color filter layer arranged on the encapsulation layer; and a cover layer arranged on the color filter layer, wherein the cover layer includes a first surface, which is in contact with the color filter layer, and a second surface, which is a surface opposite to the first surface, and the roughness of the second surface is changed by power applied to the cover layer.

A display device according to embodiments of the present disclosure includes: a display panel and an optical device arranged in the display panel, wherein the display panel includes: a substrate: a circuit layer arranged on the substrate; a light-emitting element layer arranged on the circuit layer; an encapsulation layer arranged on the light-emitting element layer; a color filter layer arranged on the encapsulation layer; and a cover layer arranged on the color filter layer, wherein the cover layer includes: a plurality of first active electrodes arranged to be spaced apart from each other on the color filter layer: a plurality of second active electrodes arranged to be spaced apart from the first active electrodes: and an electroactive layer configured to cover the first active electrodes and the second active electrodes.

The embodiments according to the present disclosure may improve the display quality of the display device by using a cover layer incorporating an anti-reflection function.

The embodiments according to the present disclosure may provide the cover layer incorporating an anti-reflection function by using an electroactive polymer.

The embodiments according to the present disclosure may implement the anti-reflection function when the intensity of external light is equal to or higher than a preset intensity since the electroactive polymer is selectively activated based on an illuminance sensor. Accordingly, with the electroactive polymer deactivated, the display device may achieve higher resolution than a display device with an anti-reflection film applied thereto, even with low-power operation.

The embodiments according to the present disclosure may increase the degree of freedom in design of the display device by providing various embodiments of active electrodes arranged to activate the electroactive polymer.

The embodiments according to the present disclosure may provide an arrangement of active electrodes to prevent or minimize an occurrence of a Moire.

The embodiments according to the present disclosure may eliminate the use of a conventional cover glass by using the cover layer incorporating the anti-reflection function.

Various useful advantages and effects of the embodiments are not limited to the above-described contents and will be more easily understood from descriptions of the specific embodiments.

### BRIEF DESCRIPTION OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a view showing a display panel and an optical device of a display device according to an embodiment of the present disclosure;

FIG. 2 is a cross-sectional view schematically showing the display panel according to an embodiment of the present disclosure;

FIG. 3 is a cross-sectional view showing a cross-sectional structure of a pixel area arranged in a display area of the display panel according to an embodiment of the present disclosure;

FIGS. 4A and 4B are a view showing an electroactive layer whose surface roughness varies depending on whether power is applied in the display panel according to an embodiment of the present disclosure;

FIG. 5 is a view showing a first embodiment of an arrangement relationship of active electrodes arranged in the display panel according to an embodiment of the present disclosure;

FIG. 6 is a view showing a second embodiment of an arrangement relationship of active electrodes arranged in the display panel according to an embodiment of the present disclosure;

FIG. 7 is a view showing a vehicle in which an active electrode is arranged according to the second embodiment;

FIG. 8 is a view showing a third embodiment of an arrangement relationship of active electrodes arranged in the display panel according to an embodiment of the present disclosure;

FIG. 9 is a view showing a fourth embodiment of an arrangement relationship of active electrodes arranged in the display panel according to an embodiment of the present disclosure; and

FIG. 10 is a view showing a fifth embodiment of an arrangement relationship of active electrodes arranged in the display panel according to an embodiment of the present disclosure.

### DETAILED DESCRIPTION OF EXEMPLARY EMBODIMENTS

The advantages and features of the present disclosure and methods for accomplishing the same will be more clearly understood from embodiments described below with reference to the accompanying drawings. However, the present disclosure is not limited to the following embodiments but may be implemented in various different forms. Rather, the present embodiments will make the disclosure of the present disclosure complete and allow those skilled in the art to completely comprehend the scope of the present disclosure.

Shapes, sizes, ratios, angles, numbers, and the like disclosed in the drawings for describing the embodiments of the present disclosure are exemplary, and the present disclosure is not limited to the illustrated items. Like reference numerals refer to like elements throughout. In addition, in describing the present disclosure, if it is determined that the detailed description of the related known technology may unnecessarily obscure the subject matter of the present disclosure, the detailed description thereof will be omitted.

The terms such as “comprising”, “including”, “having” and “consisting of” used herein are generally intended to allow other components to be added unless the terms are used with the term “only”. References to the singular shall be construed to include the plural unless expressly stated otherwise.

In interpreting a component, it is interpreted to include an error range even if there is no separate description.

In the case of a description of a positional relationship, for example, when the positional relationship of two parts is described as ‘on,’ ‘at an upper portion,’ ‘at a lower portion,’ ‘next to, and the like, one or more other parts may be located between the two parts unless ‘immediately’ or ‘directly’ is used.

In the description for the embodiments, the first, second, etc. are used to describe various components, but these components are not limited by these terms. These terms are only used to distinguish one component from another. Therefore, the first component mentioned below may be a second component within the technical spirit of the present disclosure.

Throughout the specification, the same reference numerals refer to the same component.

The features of each of the various embodiments may be combined or linked with each other, in whole or in part, and various technical interlocking and driving may be possible, and each of the embodiments may be implemented independently of each other or in conjunction with each other.

Recently, the importance of a display device as a visual information transmission medium has been further emphasized in information-oriented society, and display devices are being improved to meet requirements, such as low power consumption, reduction of thickness, weight reduction, high definition, high efficiency, and the like.

A display device according to an embodiment of the present disclosure may incorporate an anti-reflection function through a cover layer including an electroactive polymer.

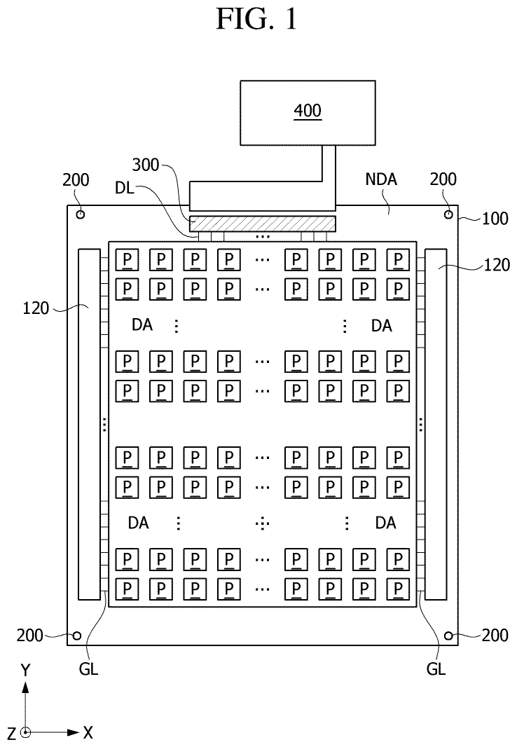

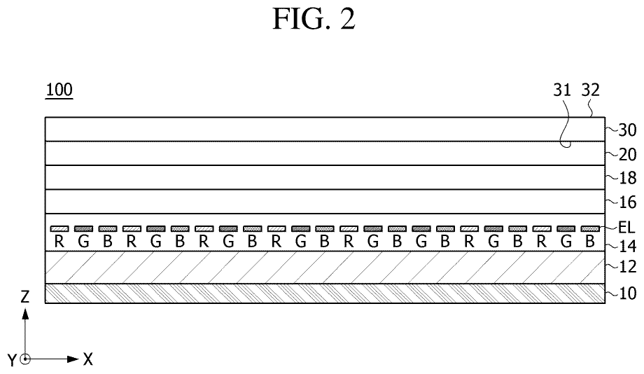

FIG. 1 is a view showing a display panel and an optical device of a display device according to an embodiment of the present disclosure. FIG. 2 is a cross-sectional view schematically showing the display panel according to an embodiment of the present disclosure.

Referring to FIGS. 1 to 2, the display device according to an embodiment of the present disclosure may include a display panel 100 and an optical device 200. In addition, the display device may further include a case (not illustrated) that protects the display panel 100 and the optical device 200. Here, the optical device 200 may be an illuminance sensor that senses how much light reaches per unit area, but embodiments of the present specification are not necessarily limited thereto. In addition, the optical device 200 may include an image sensor (or camera), a proximity sensor, a white light illumination element, an optical element for facial recognition, and the like. For example, the optical device 200 may further include at least one of an image sensor, a proximity sensor, a gesture sensor, a motion sensor, a fingerprint recognition sensor, or a biometric sensor.

The display panel 100 may implement the display of information, video, and/or an image provided to a user. For example, the display panel 100 may include a display area DA that implements the display of information, video, and/or an image, and a non-display area NDA that surrounds the display area DA.

The display area DA may be an area where a video is displayed. The display area DA may include a plurality of pixels P. Each of the plurality of pixels P may be composed of a plurality of sub-pixels. A plurality of light-emitting elements may be arranged in each of the plurality of sub-pixels. The plurality of light-emitting elements may be configured differently depending on the type of display device. For example, if the display device is an inorganic light-emitting display device, the light-emitting element may be a light-emitting diode (LED), a micro light-emitting diode (micro LED), or a mini light-emitting diode (mini LED), but embodiments of the present specification are not limited thereto. For example, if the display device is an organic light-emitting display device, the light-emitting element may be an organic light-emitting diode (OLED).

The non-display area NDA may be an area where no video is displayed. Various wires, circuits, and the like may be arranged in the non-display area NDA for driving the plurality of pixels P of the display area DA. For example, various wire and driver circuits may be mounted in the non-display area NDA, and a pad to which an integrated circuit, a printed circuit, and the like are connected may be arranged in the non-display area NDA, but embodiments of the present specification are not limited thereto.

The driver circuit may be a data driver circuit and/or a gate driver circuit, but embodiments of the present specification are not limited thereto. Wires configured to transmit control signals for controlling the driver circuits may be arranged in the display panel 100. For example, the control signals may include various timing signals including a clock signal, an input data enable signal, and synchronization signals, but embodiments of the present specification are not limited thereto. In this case, the control signals may be received through the pad. For example, link wires for transmitting signals may be arranged in the non-display area NDA. For example, driving components such as a flexible circuit board and a printed circuit board may be connected to the pad.

According to the present specification, the non-display area NDA may include a bending area. Here, the bending area may be a bendable area. In this case, the remaining area of a substrate 10, excluding the bending area, may be in a flat state. In addition, the pad may be arranged on the non-display area NDA.

The display panel 100 may have a width in the X-axis direction, a length in the Y-axis direction, and a thickness in the Z-axis direction. Here, the width and length of the display panel 100 may be set to various design values depending on application fields of the display device. In addition, the X-axis direction may mean a width direction or a horizontal direction, the Y-axis direction may mean a longitudinal direction or a vertical direction, and the Z-axis direction may mean a vertical direction, a stacking direction, or a thickness direction. Here, the X-axis direction, the Y-axis direction, and the Z-axis direction may be perpendicular to each other, but may also mean different directions that are not perpendicular to each other. Each of the X-axis direction, the Y-axis direction, and the Z-axis direction may be described as one of a first direction, a second direction, or a third direction. Further, the plane extended in the X-axis direction and the Y-axis direction may mean a horizontal plane.

The display panel 100 may include a circuit layer 12 disposed on the substrate 10, a light-emitting element layer 14 disposed on the circuit layer 12, a encapsulation layer 16 disposed on the light-emitting element layer 14, a color filter layer 20 disposed on the encapsulation layer 16 and a cover layer 30 disposed on the color filter layer 20. In addition, the display panel 100 may further include a touch sensor layer 18 disposed between the encapsulation layer 16 and the color filter layer 20.

The substrate 10 may be formed of an insulating material or a material having flexibility. For example, the substrate 10 may be made of glass, metal, or plastic, but is not limited thereto.

The substrate 10 may include the display area DA and the non-display area NDA. The display area DA and the non-display area NDA are not limited to being described only with respect to the substrate 10 but may be described across the entire display device or the entire display panel.

The circuit layer 12 may include a pixel circuit connected to wirings such as data lines, gate lines, and power lines, a gate driver connected to the gate lines, and the like. Further, the circuit layer 12 may include transistors implemented with thin film transistors (TFTs) and circuit elements such as capacitors or the like. Here, the wirings and circuit elements of the circuit layer 12 may be implemented with a plurality of insulating layers, two or more metal layers separated with the insulating layer interposed therebetween, and an active layer including a semiconductor material.

The light-emitting element layer 14 may include a light-emitting element driven by a pixel circuit. Here, the light-emitting element may be implemented with an organic light emitting diode (OLED). The OLED may include an organic compound layer formed between an anode and a cathode. The organic compound layer includes a hole injection layer (HIL), a hole transport layer (HTL), an emission layer (EML), an electron transport layer (ETL), and an electron injection layer (EIL), but is not limited thereto. When a voltage is applied to an anode and a cathode of the OLED, the holes passing through the hole transport layer (HTL) and the electrons passing through the electron transport layer (ETL) may be moved to the light emitting layer (EML) to form excitons and emit visible light from the light emitting layer (EML).

The light-emitting element layer 14 may further include a color filter array disposed on the pixels to selectively transmit red, green, and blue wavelengths.

The light-emitting element layer 14 may be covered by a protective film, and the protective film may be covered by an encapsulation layer 16. Here, the protective film may have a structure in which organic films and inorganic films are alternately stacked. In this case, the inorganic film may block penetration of moisture or oxygen. In addition, the organic film may planarize the surface of the inorganic film. When the organic film and the inorganic film are stacked in multiple layers, a movement path of moisture or oxygen is longer than that of a single layer, so that the penetration of moisture/oxygen affecting the light-emitting element layer 14 may be effectively blocked.

The encapsulation layer 16 covers the light-emitting element layer 14 so as to seal the circuit layer 12 and the light-emitting element layer 14. Here, the encapsulation layer 16 may have a multi-insulation film structure in which the organic film and the inorganic film are alternately stacked. In this case, the inorganic film blocks penetration of moisture or oxygen. In addition, the organic film planarizes the surface of the inorganic film. When the organic film and the inorganic film are stacked in multiple layers, the movement path of moisture or oxygen is longer than that of a single layer, so that the penetration of moisture/oxygen affecting the light-emitting element layer 14 may be effectively blocked.

The touch sensor layer 18 may include capacitive touch sensors that sense a touch input based on a change in capacitance before and after the touch input. The touch sensor layer 18 may include metal wiring patterns and insulating films forming capacitance of the touch sensors. The insulating films may insulate portions in which the metal wiring patterns are intersected and planarize the surface of the touch sensor layer.

The color filter layer 20 may be formed on the touch sensor layer 18. The color filter layer 20 may include red, green, and blue color filters. In addition, the color filter layer may further include a black matrix pattern. The color filter layer 20 may absorb some wavelengths of light reflected from the circuit layer 12 to replace the role of a polarizing plate and increase color purity.

The color filter layer 20 may include an organic film covering the color filter and the black matrix pattern. An extended portion of the organic film may cover the remaining inorganic film or the substrate 10 in the bezel area, that is, the edge area of the display panel 100.

The display device according to embodiment of the present disclosure may include the display panel 100 having a pixel array arranged on a screen, the display panel driver, etc.

The pixel array of the display panel 100 may include data lines DL, gate lines GL intersecting the data lines DL, and pixels P connected to the data lines DL and gate lines GL and arranged in a matrix.

The pixel array may be divided into a circuit layer 12 and a light-emitting element layer 14, as shown in FIG. 2. Then, a touch sensor array may be arranged on the light-emitting element layer 14. Here, each of the pixels of the pixel array may include two to four sub-pixels. Each of the sub-pixels may include a pixel circuit arranged in the circuit layer 12.

Each of the sub-pixels of the display area DA may include a pixel circuit. The pixel circuit may include a driving element to supply current to the light-emitting element (OLED), a plurality of switching elements to sample a threshold voltage of the driving element and switch a current path of the pixel circuit, a capacitor to maintain a gate voltage of the driving element, etc. In this case, the pixel circuit may be arranged below the light-emitting element.

The display panel driver may write pixel data of an input image into the pixels P. The pixels may be interpreted as a pixel group including a plurality of sub-pixels.

The display panel driver may include a data driver that supplies a data voltage of pixel data to the data lines DL and a gate driver 120 that sequentially supplies gate pulses to the gate lines GL. Further, the data driver may be integrated into the drive IC 300. In addition, the display panel driver may further include a touch sensor driver omitted from the drawings.

The drive IC 300 may be bonded on the display panel 100. The drive IC 300 receives pixel data of an input image and a timing signal from the host system 400, supplies a data voltage of the pixel data to pixels, and synchronizes the data driver and the gate driver 120.

The drive IC 300 may be connected to the data lines DL through data output channels to supply data voltages of pixel data to the data lines DL. The drive IC 300 may output a gate timing signal for controlling the gate driver 120 through gate timing signal output channels.

The gate driver 120 may include a shift register formed on a circuit layer of the display panel 100 together with a pixel array. The shift register of the gate driver 120 may sequentially supply gate signals to the gate lines GL under the control of the timing controller. The gate signal may include a scan pulse and an EM pulse of an emission signal.

The host system 400 may be implemented with an application processor (AP). The host system 400 may transmit pixel data of an input image to the drive IC 300 through a mobile industry processor interface (MIPI). The host system 400 may be connected to the drive IC 300 through a flexible printed circuit (FPC).

Meanwhile, the display panel 100 may be implemented with a flexible panel applicable to a flexible display.

The flexible panel may be made of a so-called “plastic OLED panel”. The plastic OLED panel may include a back plate and a pixel array on an organic thin film adhered on the back plate. A touch sensor array may be formed over the pixel array.

The back plate may be a polyethylene terephthalate (PET) substrate. The pixel array and the touch sensor array may be formed on the organic thin film. The back plate may block moisture permeation toward the organic thin film so that the pixel array is not exposed to humidity.

The organic thin film may be a polyimide (PI) substrate. A multi-layered buffer film may be formed on the organic thin film with an insulating material. Further, the circuit layer 12 and the light-emitting element layer 14 may be stacked on the organic thin film.

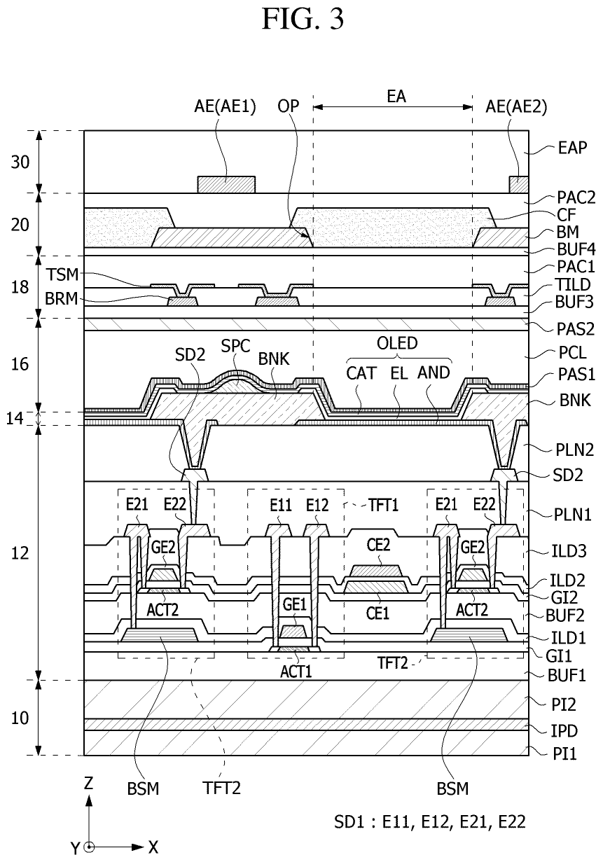

FIG. 3 is a cross-sectional view of a cross-sectional structure of a pixel area disposed in a display area in a display panel according to an embodiment of the present invention. Here, it should be noted that the cross-sectional structure of the pixel area is not limited to that of FIG. 3. In FIG. 3, TFT may represent a driving element of the pixel circuit. In detail, TFT1 may be a first TFT that is one of LTPS TFTs disposed in the display area, and TFT2 may be a second TFT that is one of oxide TFTs disposed in the display area.

Referring to FIG. 3, a plurality of pixel circuits and wires connected to the pixel circuits may be disposed in the display area DA of the display panel 100. Here, the pixel circuits of the display area may include a pixel circuit of a red sub-pixel driving a red light-emitting element, a pixel circuit of a green sub-pixel driving a green light-emitting element, and a pixel circuit of a blue sub-pixel driving a blue light-emitting element. Further, the pixel circuits may be separated into a plurality of circuit areas along the X-axis direction of the display panel 100 within the display area DA.

The substrate 10 may include first and second substrates PI1 and PI2. In addition, an inorganic film IPD may be formed between the first substrate PI1 and the second substrate PI2. In this case the inorganic film IPD may block moisture permeation. Here, since the substrate 10 may be formed of polyimide, it may be referred to as a PI substrate, and the first and second substrates PI1 and PI2 may be referred to as first and second PI substrates.

The first buffer layer BUF1 may be formed on the second substrate PI2. The first buffer layer BUF1 may be formed of a multi-layered insulating layer in which two or more oxide (e.g., SiO₂) layers and nitride (SiNx) layers are stacked. A first semiconductor layer is formed on the first buffer layer BUF1. The first semiconductor layer may include a polysilicon semiconductor layer patterned in a photolithography process. The first semiconductor layer may include a polysilicon active pattern ACT1 forming a semiconductor channel in the first TFT TFT1.

A first gate insulating layer GI1 is deposited on the first buffer layer BUF1 to cover the active pattern ACT1 of the first semiconductor layer. The first gate insulating layer GI1 includes an inorganic insulating material layer. A first metal layer is formed on the first gate insulating layer GI1. The first metal layer is insulated from the first semiconductor layer by the first gate insulating layer GI1.

The first metal layer may include a single metal layer patterned in a photolithography process or metal patterns in which two or more metal layers are stacked. The first metal layer may include the gate electrode GE1 of the first TFT (TFT1) and a light shield pattern BSM under the second TFT (TFT 2).

A first interlayer insulating layer ILD1 is formed on the first gate insulating layer GI1 to cover the patterns of the first metal layer. The first interlayer insulating layer ILD1 may include an inorganic insulating material. A second buffer layer BUF2 is formed on the first interlayer insulating layer ILD1. The second buffer layer BUF2 may include a single layer or a multi-layer inorganic insulating material.

The second semiconductor layer may include an oxide semiconductor pattern ACT2 forming a semiconductor channel in the second TFT TFT2. The second gate insulating layer GI2 may be deposited on the second buffer layer BUF2 to cover the active pattern ACT2 of the second semiconductor layer. The second gate insulating layer GI2 may include a single or multi-layered inorganic insulating material. A second metal layer may be formed on the second gate insulating layer GI2. The second metal layer may be insulated from the second semiconductor layer by the second gate insulating layer GI2.

The second metal layer may include a single metal layer patterned in a photolithography process or metal patterns in which two or more metal layers are stacked. The second metal layer may include a gate electrode GE2 of the second TFT TFT2 and a lower capacitor electrode CE1.

A second interlayer insulating layer ILD2 may be formed on the second gate insulating layer GI2 to cover the patterns of the second metal layer. The second interlayer insulating layer ILD2 may include a single layer or a multi-layer inorganic insulating material. A third metal layer may be formed on the second interlayer insulating layer ILD2. The third metal layer may be insulated from the second metal layer by the second interlayer insulating layer ILD2.

The third metal layer may include a single metal layer patterned in a photolithography process or metal patterns in which two or more metal layers are stacked. The third metal layer may include an upper capacitor electrode CE2. The capacitor Cst of the pixel circuit may be composed of the upper capacitor electrode CE2, the lower capacitor electrode CE1, and a dielectric layer therebetween, that is, the second interlayer insulating layer ILD2.

A third interlayer insulating layer ILD3 covering the patterns of the third metal layer may be formed on the second interlayer insulating layer ILD2. The third interlayer insulating layer ILD3 may include a single layer or a multi-layer inorganic insulating material. A fourth metal layer may be formed on the third interlayer insulating layer ILD3. The fourth metal layer may be insulated from the second semiconductor layer by the second gate insulating layer GI2.

A fourth metal layer SD1 may include a single metal layer patterned in a photolithography process or metal patterns in which two or more metal layers are stacked. The fourth metal layer may include first and second electrodes E11 and E12 of the first TFT TFT1 and first and second electrodes E21 and E22 of the second TFT TFT2. The first and second electrodes E11 and E12 of the first TFT TFT1 may be connected to a first active pattern ACT1 through a first contact hole passing through the insulating layers GI1, ILD1, BUF2, GI2, ILD2 and ILD3. The first and second electrodes E21 and E22 of the second TFT TFT2 may be connected to a second active pattern ACT2 through a second contact hole passing through the insulating layers GI2, ILD2 and ILD3. The first electrode E21 of the second TFT TFT2 may be connected to the light shield pattern BSM through a third contact hole passing through the insulating layers ILD1, BUF2, GI2, ILD2 and ILD3. Here, a strong electric field may be generated in the metal patterns E11 to E22 of the fourth metal layer due to voltages swinging between a gate-on voltage and a gate-off voltage with a large voltage difference.

A first planarization layer PLN1 may cover the patterns E11 to E22 of the fourth metal layer. The first planarization layer PLN1 may thickly cover the display area DA of the circuit layer 12 with an organic insulating material. When the first planarization layer PLN1 is applied on the circuit layer 12, the organic insulating material may flow to the edge of the display panel 100 and cover the side surface of the circuit layer 12.

A fifth metal layer may be formed on the first planarization layer PLN1. The fifth metal layer may be insulated from the fourth metal layer by the first planarization layer PLN1. The fifth metal layer may include a single metal layer patterned in a photolithography process or metal patterns in which two or more metal layers are stacked. The fifth metal layer may include a metal pattern SD2 connecting the light-emitting element to the second TFT TFT2. The metal pattern SD2 may be connected to the second electrode E22 of the second TFT TFT2 through a fourth contact hole penetrating the first planarization layer PLN1.

A second planarization layer PLN2 may be formed on the first planarization layer PLN1 to cover the metal patterns of the fifth metal layer. The second planarization layer PLN2 may thickly cover the display area DA of the circuit layer 12 with an organic insulating material. A sixth metal layer may be formed on the second planarization layer PLN2. The second planarization layer PLN2 may planarize the surface on which the sixth metal layer is formed.

The sixth metal layer may include a single metal layer patterned in a photolithography process or metal patterns in which two or more metal layers are stacked. The pattern of the sixth metal layer may include an anode electrode AND of the light-emitting element. The anode electrode AND may be in contact with the metal pattern SD2 connected to the second TFT TFT2 of the pixel circuits through the fifth contact hole penetrating the second planarization layer PLN2.

In the light-emitting element layer 14, a bank BNK may be formed on the second planarization layer PLN2 to cover the edge of the anode AND. In this case, the bank BNK may be formed in a pattern that divides a light emitting area (or an opening area) from which light is emitted from each pixel to the outside. Accordingly, the bank BNK may be referred to as a pixel-defining film. The bank BNK may be patterned in a photolithography process by including an organic insulating material having photosensitivity. Further, a spacer SPC having a predetermined height may be formed on the bank BNK. In this case, the bank BNK and the spacer SPC may be integrated with the same organic insulating material. Further, the spacer SPC secures a gap between a fine metal mask (FMM) and the anode electrode AND so that the FMM is not in contact with the anode electrode AND during a deposition process of the light-emitting element formed of an organic compound.

A seventh metal layer used as a cathode electrode CAT of the light-emitting element may be formed on the bank BNK and an organic compound layer EL. The seventh metal layer may be connected between sub-pixels in the display area DA. Here, the organic compound layer EL may be referred to as a light emitting layer or an electroluminescent layer.

The encapsulation layer 16 may include multiple insulating layers covering the cathode electrode CAT of the light-emitting element. The multiple insulating layers may include a first inorganic insulating layer PAS1 covering the cathode electrode CAT, a thick organic insulating layer PCL covering the first inorganic insulating layer PAS1, and a second inorganic insulating layer PAS2 covering the organic insulating layer PCL.

The touch sensor layer 18 may include: a third buffer layer BUF3 configured to cover the second inorganic insulating layer PAS2; a bridge metal BRM arranged on the third buffer layer BUF3; a touch interlayer insulating layer TILD made of an inorganic material and configured to cover the bridge metal BRM; a touch sensor metal TSM arranged on the bridge metal BRM; and a first insulating layer PAC1 configured to cover the touch interlayer insulating layer TILD and the touch sensor metal TSM. Here, the third buffer layer BUF3 may be a touch buffer layer. In addition, the first insulating layer PAC1 may include an organic insulating material.

The third buffer layer BUF3 may include a single-layer or multi-layer inorganic insulating material. For example, the third buffer layer BUF3 may be formed as a multi-layer insulating film in which two or more layers of oxide (e.g., SiO₂) films and nitride (SiNx) films are stacked.

An eighth metal layer used as the bridge metal BRM may be arranged on the third buffer layer BUF3, and may overlap the bank BNK. The eighth metal layer may include a single-layer metal patterned in a photolithography process or metal patterns in which two or more metal layers are stacked.

A ninth metal layer may include a single-layer metal patterned in a photolithography process or metal patterns in which two or more metal layers are stacked. The pattern of the ninth metal layer may include the touch sensor metal TSM. The touch sensor metal TSM may come into contact the bridge metal BRM through a sixth contact hole configured to penetrate the touch interlayer insulating layer TILD.

The color filter layer 20 may include: a fourth buffer layer BUF4 configured to cover the first insulating layer PAC1; a black matrix BM arranged on the fourth buffer layer BUF4 and configured to include an opening OP; a color filter CF arranged in the opening OP of the black matrix BM; and a second insulating layer PAC2 configured to cover the black matrix BM and the color filter CF. Here, the fourth buffer layer BUF4 may be a color filter buffer layer. In addition, the second insulating layer PAC2 may include an organic insulating material, and may be a color filter insulating layer.

The fourth buffer layer BUF4 may include a single-layer or multi-layer inorganic insulating material. For example, the fourth buffer layer BUF4 may be formed as a multilayer insulating film in which two or more layers of oxide (e.g., SiO₂) films and nitride (SiNx) films are stacked.

The black matrix BM may be formed of a material with high optical density (OD). Accordingly, the black matrix BM may absorb or block light.

The black matrix BM may overlap the touch sensor metal TSM and the bridge metal BRM. Accordingly, the black matrix BM may prevent external light from being reflected by the touch sensor metal TSM and the bridge metal BRM.

The color filter CF may be arranged to correspond to a light-emitting area EA of the light-emitting element OLED, and may include a color of any one of red, green, or blue.

The color filter CF may include a red color filter, a green color filter, and a blue color filter, each corresponding to the color of a respective sub-pixel. Accordingly, the color filter CF may be arranged in the opening OP of the black matrix BM. In addition, the color filter CF may overlap the light-emitting area EA in the Z-axis direction.

The second insulating layer PAC2 may be arranged on the black matrix BM and the color filter CF. In addition, the second insulating layer PAC2 may be formed of an organic insulating material such as polyimide or acrylic resin.

The cover layer 30 may be arranged on the color filter layer 20.

The cover layer 30 may include a first surface 31, which is in contact with the color filter layer 20, and a second surface 32, which is a surface opposite to the first surface 31 with respect to the Z-axis direction. Here, the first surface 31 may be a bottom or lower surface of the cover layer 30, and the second surface 32 may be a top or upper surface of the cover layer 30. Here, the second surface 32 may be a surface that is exposed to the outside, and may constitute a top surface of the display panel 100. Accordingly, the cover layer 30 may be used as a cover member of the display panel 100.

The cover layer 30 may include a plurality of active electrodes AE arranged on the second insulating layer PAC2, electrode wires configured to connect the plurality of active electrodes AE, and an electroactive layer EAP arranged to cover the plurality of active electrodes AE. Here, the active electrodes AE may include a plurality of first active electrodes AE1 and second active electrodes AE2. In addition, the electrode wires may include a first electrode wire EL1 configured to connect the first active electrodes AE1 and a second electrode wire EL2 configured to connect the second active electrodes AE2. Accordingly, a voltage may be formed between the first active electrodes AE1 and the second active electrodes AE2 so as to electrically stimulate the electroactive layer EAP.

A tenth metal layer may include a single-layer metal patterned in a photolithography process or metal patterns in which two or more metal layers are stacked. The pattern of the tenth metal layer may include the active electrode AE and the electrode wires EL1 and EL2.

The plurality of active electrodes AE may be arranged to be spaced apart from each other on the second insulating layer PAC2. The plurality of active electrodes AE may overlap the black matrix BM of the color filter layer 20 in the Z-axis direction. For example, the first active electrodes AE1 and the second active electrodes AE2 may overlap the black matrix BM of the color filter layer 20 in the Z-axis direction, but embodiments of the present specification are not necessarily limited thereto.

The active electrodes AE may be formed of a transparent conductive material. For example, the active electrodes AE may be formed of a transparent metal material. For example, the active electrodes AE may be composed of a transparent conductive material such as indium tin oxide (ITO), indium zinc oxide (IZO), or indium gallium zinc oxide (IGZO), but embodiments of the present specification are not necessarily limited thereto.

The active electrodes AE may include the plurality of first active electrodes AE1 and second active electrodes AE2 arranged to be spaced apart from each other on the second insulating layer PAC2. Accordingly, power may be applied to the electroactive layer EAP through the plurality of first active electrodes AE1 and second active electrodes AE2. In this case, the active electrodes AE may be electrically connected to wires arranged in the circuit layer 12 through the first electrode wire EL1 and the second electrode wire EL2, but embodiments of the present specification are not necessarily limited thereto.

The first electrode wire EL1 and the second electrode wire EL2 may be formed of a transparent conductive material. For example, the first electrode wire EL1 and the second electrode wire EL2 may be formed of a transparent metal material. For example, the first electrode wire EL1 and the second electrode wire EL2 may be composed of a transparent conductive material such as indium tin oxide (ITO), indium zinc oxide (IZO), or indium gallium zinc oxide (IGZO), but embodiments of the present specification are not necessarily limited thereto.

The electroactive layer EAP may be arranged to cover the active electrodes AE, the first electrode wire EL1, and the second electrode wire EL2. Accordingly, a top surface of the electroactive layer EAP may be provided as the second surface 32 of the cover layer 30.

The electroactive layer EAP may include an electroactive polymer.

The electroactive polymer may be a polymer material that changes in shape, size, or mechanical properties in response to electrical stimulation. For example, the electroactive polymer may be a polymer material that changes in shape, size, surface roughness, or the like in response to electrical stimulation.

The shape, size, mechanical properties, or the like of the electroactive polymer may change based on the principles of ion migration and ion absorption.

The principle of ion migration is that ions (cations or anions) move within a polymer in response to electrical stimulation, thereby changing the charge and size of the polymer. Accordingly, the length or shape of the polymer material may change.

In addition, the principle of ion absorption is that when a polymer is exposed to an electric field, the polymer absorbs ions and the volume of the polymer changes. Accordingly, by adjusting the voltage between the cathode and anode, the volume of a material may change.

Therefore, the display panel 100 according to an embodiment of the present specification may change the shape, size, mechanical properties, or the like of the electroactive layer EAP through at least one of the principles of ion migration and ion absorption. For example, the display panel 100 according to an embodiment of the present specification may change the roughness of an upper surface of the electroactive layer EAP by applying power. Accordingly, the upper surface of the electroactive layer EAP with the changed roughness may scatter light emitted from the outside to the display device, thereby implementing an anti-reflection function of the display device.

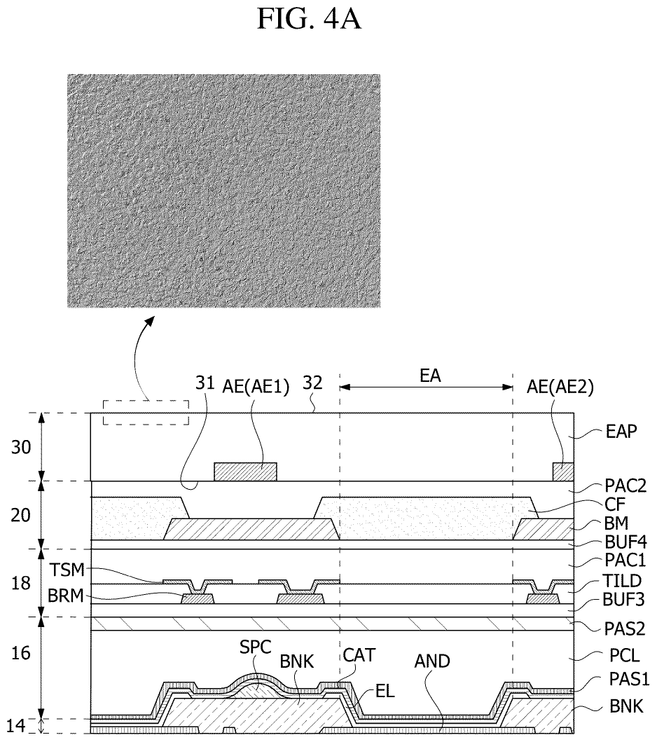

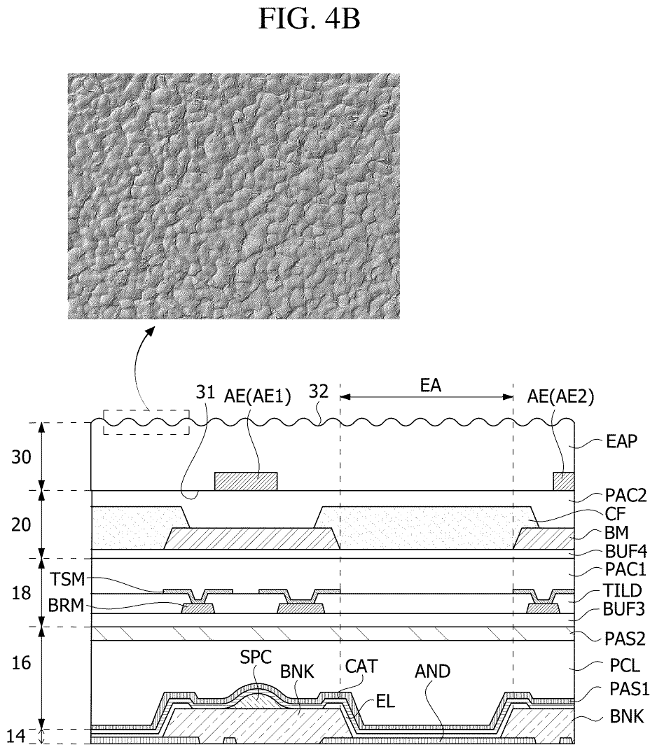

FIGS. 4A and 4B are a view showing an electroactive layer whose surface roughness varies depending on whether power is applied in the display panel according to an embodiment of the present disclosure. For example, FIG. 4A is a conceptual view showing the electroactive layer EAP that is deactivated, and FIG. 4B is a conceptual view showing the electroactive layer EAP that is activated. In FIGS. 4A and 4B, enlarged images may show a top surface of the electroactive layer EAP, which appears depending on whether the electroactive layer EAP is activated.

Referring to FIG. 4A, when the intensity of external light is lower than a preset intensity, reflection caused by electrodes arranged inside the display panel 100 is minimized, and thus, the electroactive layer EAP may be deactivated based on a signal output from an illuminance sensor 200. Accordingly, since the deactivated electroactive layer EAP may implement the second surface 32, which has lower roughness compared to the activated electroactive layer EAP, the display device may achieve higher resolution than a display device with an anti-reflection film applied thereto, even with low-power operation. For example, since the electroactive polymer in the display panel 100 illustrated in FIG. 4A is deactivated, the display device may achieve higher resolution than a display device with an anti-reflection film applied thereto, even with low-power operation. Here, the intensity of external light may be detected by the illuminance sensor 200.

When the intensity of external light is equal to or higher than a preset intensity, the external light may be reflected by the electrodes arranged inside the display panel 100, thereby forming reflected light. Accordingly, the reflected light may be perceived by a user using the display device, thereby reducing the display quality of the display device.

Therefore, the display panel 100 may activate the electroactive layer EAP based on a signal from the illuminance sensor 200, thereby implementing the anti-reflection function of the cover layer 30. Accordingly, the display quality of the display device may be improved.

As illustrated in FIG. 4B, since the display panel 100 implements the second surface 32, which has greater roughness compared to the deactivated electroactive layer EAP by activating the electroactive layer EAP, external light may be scattered from the second surface 32, which is the top surface of the electroactive layer EAP. Accordingly, the intensity of light entering the display panel 100 may be reduced by the activated electroactive layer EAP.

In addition, even when a portion of the scattered external light is reflected by the electrodes arranged inside the display panel 100 to form reflected light, the reflected light is scattered from the second surface 32 of the electroactive layer EAP, and thus, the reduction in the quality of the display device caused by the reflected light may be prevented or minimized. In this case, a portion of the external light scattered from the second surface 32 may be absorbed by the black matrix BM.

Therefore, the display panel 100 according to embodiments of the present disclosure may improve the display quality of the display device against external light by changing the roughness of the second surface 32 of the cover layer 30 through power applied to the cover layer 30 based on the signal of the illuminance sensor 200. That is, for the display device according to embodiments of the present disclosure, the anti-reflection function may be selectively activated or deactivated depending on the user environment, thereby enhancing user convenience.

The plurality of active electrodes AE may include the plurality of first active electrodes AE1 and the plurality of second active electrodes AE2. In this case, the first active electrodes AE1 may be patterned in a first pattern and the second active electrodes AE2 may be patterned in a second pattern.

The first active electrodes AE1 formed in the first pattern and the second active electrodes AE2 formed in the second pattern may provide various embodiments through a shape, size, arrangement relationship, and combination thereof, thereby increasing the degree of freedom in design of the display device. For example, the first active electrodes AE1 and the second active electrodes AE2 may be formed in the same shape and size, and may be arranged to be spaced apart at equal intervals. In addition, the first active electrodes AE1 and the second active electrodes AE2 may be formed in the same shape but different sizes. In this case, the first active electrodes AE1 and the second active electrodes AE2 may be spaced apart at different intervals. In addition, the first active electrodes AE1 and the second active electrodes AE2 may be formed in different shapes and different sizes. In this case, the first active electrodes AE1 and the second active electrodes AE2 may be spaced apart at different intervals.

Several embodiments of the first active electrodes AE1 formed in the first pattern and the second active electrodes AE2 formed in the second pattern will be described below.

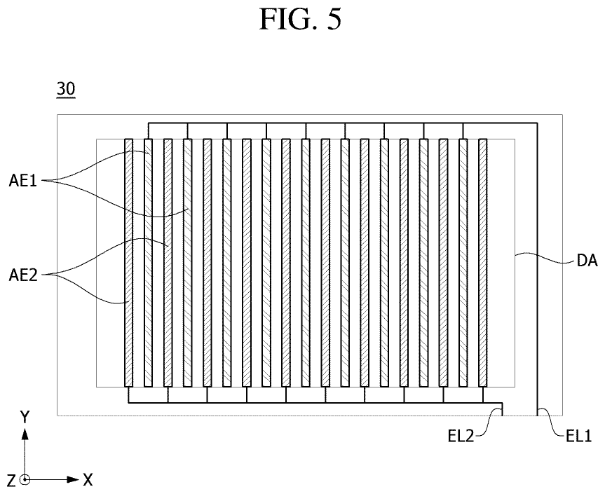

FIG. 5 is a view showing a first embodiment of an arrangement relationship of active electrodes arranged in the display panel according to an embodiment of the present disclosure.

Referring to FIG. 5, the plurality of active electrodes AE may be arranged in a striped configuration. For example, the first active electrodes AE1 and the second active electrodes AE2 may be formed in the same shape and size. As illustrated in FIG. 5, the first active electrodes AE1 and the second active electrodes AE2 may be formed in a bar shape having a width in the first direction smaller than a length in the second direction. In addition, the first active electrodes AE1 and the second active electrodes AE2 may be alternately arranged along the first direction. Here, the first direction may be the X-axis direction, and the second direction may be the Y-axis direction.

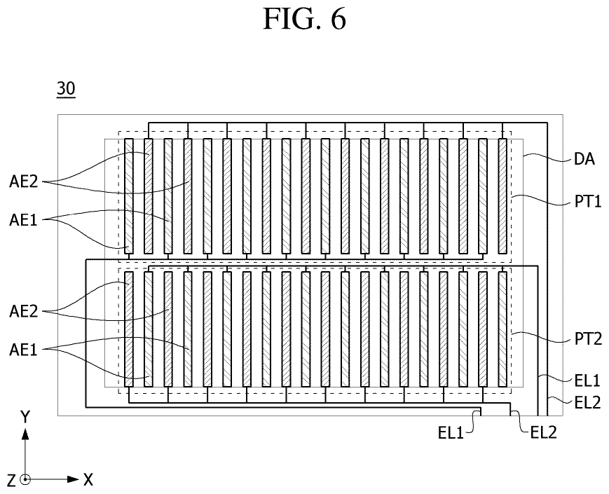

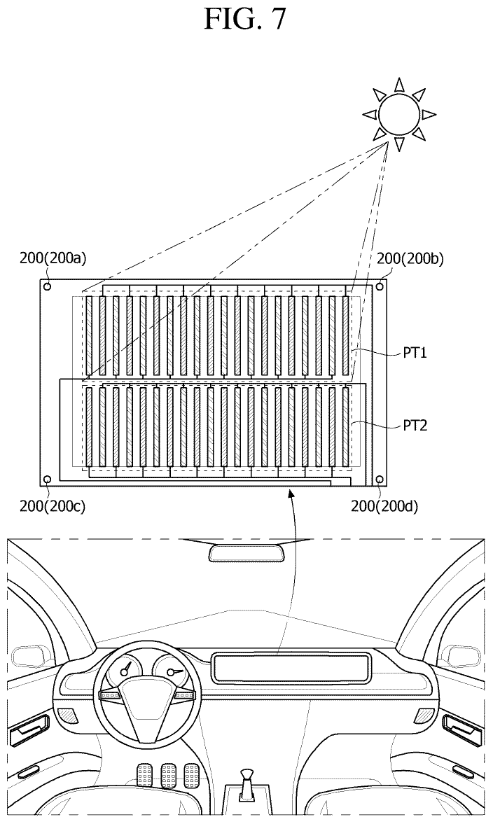

FIG. 6 is a view showing a second embodiment of an arrangement relationship of active electrodes arranged in the display panel according to an embodiment of the present disclosure. FIG. 7 is a view showing a vehicle in which an active electrode is arranged according to the second embodiment. As illustrated in FIG. 7, four illuminance sensors 200 may be arranged in the display device, but embodiments of the present specification are not limited thereto. For example, if the cover layer 30 is electrically separated and includes a plurality of parts, each being composed of a plurality of the active electrodes AE, four or more illuminance sensors 200 may be arranged in the display device, taking into account the segmented driving of the plurality of parts.

Referring to FIG. 6, the cover layer 30 may include, a first part PT1 and a second part PT2, which are electrically separated, but embodiments of the present specification are not necessarily limited thereto. For example, the cover layer 30 may include three or more electrically separated parts.

The first part PT1 and the second part PT2 may include a plurality of the first active electrodes AE1 and the second active electrodes AE2, respectively. In this case, the first active electrodes AE1 and the second active electrodes AE2 may be formed in a bar shape having a width in the first direction smaller than a length in the second direction; and the first active electrodes AE1 and the second active electrodes AE2 may be alternately arranged along the first direction.

The first part PT1 and the second part PT2 may be arranged adjacent to each other. For example, the first part PT1 and the second part PT2 may be arranged adjacent to each other in the Y-axis direction.

The first electrode wire EL1 and the second electrode wire EL2 may be connected to the first active electrode AE1 of the first part PT1 and the second active electrode AE2 of the second part PT2, respectively. Accordingly, the first part PT1 and the second part PT2 may be operated separately.

Based on the illuminance detected by each of the plurality of illuminance sensors 200, the first part PT1 and the second part PT2 may be separately operated, but embodiments of the present specification are not necessarily limited thereto. For example, if the illuminance detected by each of the plurality of illuminance sensors 200 is greater than a preset value, the first part PT1 and the second part PT2 may be operated. In addition, if the illuminance detected by each of the plurality of illuminance sensors 200 is less than the preset value, the first part PT1 and the second part PT2 may not be operated. In addition, if the illuminance detected by the illuminance sensor 200 arranged adjacent to the first part PT1 is greater than the preset value, only the first part PT1 may be driven.

Referring to FIG. 7, the display device according to embodiments of the present disclosure may be arranged in an interior of a vehicle, and external light may be emitted onto the display device through a window of the vehicle. Here, the display device may include four illuminance sensors 200 arranged at four corners thereof. In addition, the first part PT1 may be arranged at an upper portion of the second part PT2.

External light is emitted only onto a portion of the display device arranged in the interior of the vehicle, and thus, the anti-reflection function of the display panel 100 may be implemented only in the portion of the display panel 100 onto which external light is emitted. For example, external light with illuminance greater than or equal to a preset value may be emitted onto two illuminance sensors 200 arranged in the upper portion of the display device. Accordingly, only the electroactive layer EAP arranged in the first part PT1 may be activated to scatter external light. Specifically, the display device may include a first illuminance sensor 200a, a second illuminance sensor 200b, a third illuminance sensor 200c, and a fourth illuminance sensor 200d. In this case, the first illuminance sensor 200a and the second illuminance sensor 200b may be arranged adjacent to the first part PT1 in the upper portion of the display device. In addition, the third illuminance sensor 200c and the fourth illuminance sensor 200d may be arranged adjacent to the second part PT2 in a lower portion of the display device. In addition, when external light is emitted with illuminance greater than or equal to a preset value only onto the first illuminance sensor 200a and the second illuminance sensor 200b, only the electroactive layer EAP arranged in the first part PT1 is activated to scatter the external light.

The active electrodes AE may be formed of a transparent conductive material and arranged to overlap the black matrix BM. Accordingly, with the display device turned off, the active electrodes AE of the display device may prevent or minimize the formation of a Moire caused by reflected light.

The plurality of active electrodes AE formed in a single shape and size may include an opaque conductive material and may be regularly arranged. In this case, external light reflected by each of the active electrodes AE may form a Moire. For example, if the first active electrodes AE1 and the second active electrodes AE2 are formed in the same shape and size and are arranged to be spaced apart at equal intervals, reflected light formed by each of the first active electrodes AE1 and the second active electrodes AE2 may form a Moire. Specifically, if the first active electrodes AE1 and the second active electrodes AE2 are formed in the same shape and size and are arranged to be spaced apart at equal intervals, a portion of light emitted from the outside may form first reflected light by the patterned first active electrode AE1, and may form second reflected light by the patterned second active electrode AE2. In addition, the first reflected light and the second reflected light are also patterned, and thus, a Moire may be formed at a boundary (or at a certain location) between the first reflected light and the second reflected light.

In addition, external light may form a Moire due to interference between light reflected by a functional layer, which is patterned and arranged below the cover layer 30 and the patterned active electrodes AE. For example, since the functional layer is patterned, the light reflected by the functional layer may also be patterned. In addition, the reflected light may form a Moire due to the interference between the patterned reflected light and the patterned active electrodes AE. Specifically, the color filter CF is patterned to correspond to the light-emitting area EA and is formed of a material having reflectivity, and thus, light reflected by the color filter CF may be patterned. In addition, the patterned reflected light may form a Moire through the interference with the active electrodes AE.

Accordingly, the display device according to an embodiment of the present disclosure may prevent or minimize the formation of a Moire caused by the reflected light by forming the first active electrodes AE1 and the second active electrodes AE2 to have different shapes, sizes, and/or intervals, respectively.

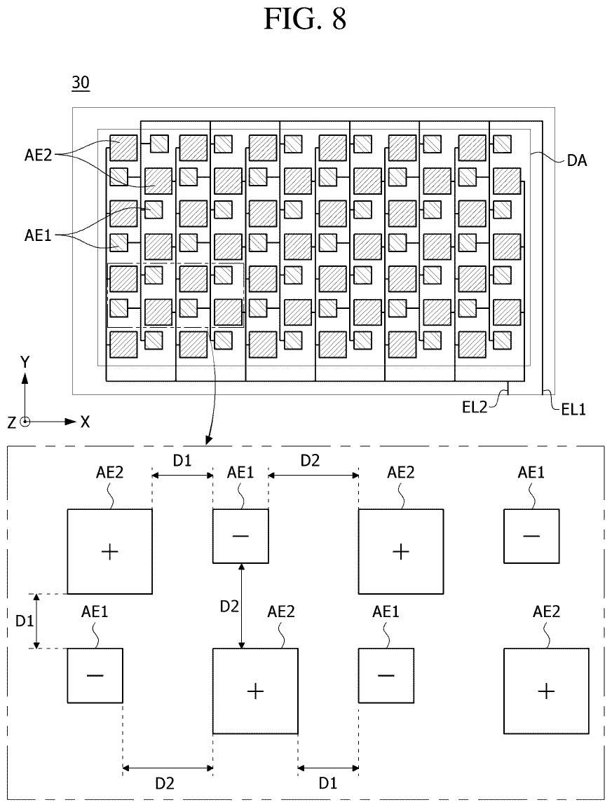

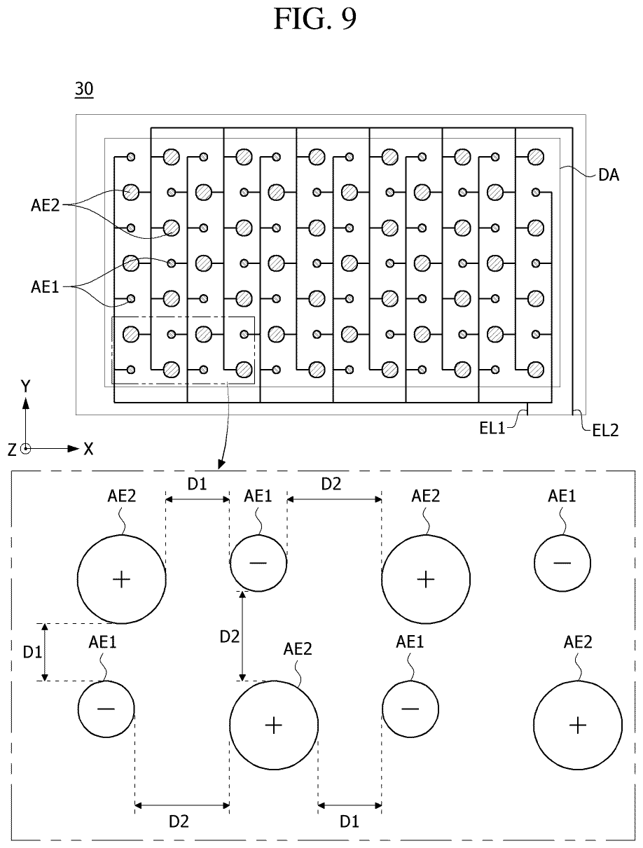

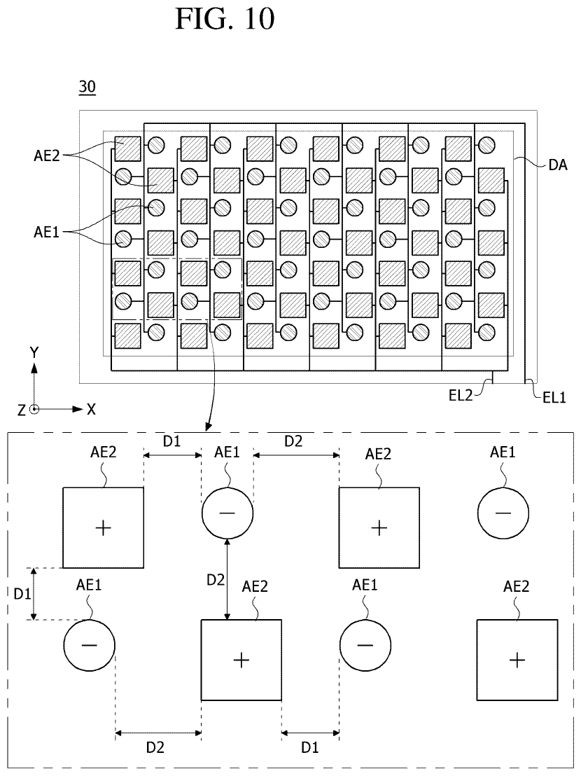

FIG. 8 is a view showing a third embodiment of an arrangement relationship of active electrodes arranged in the display panel according to an embodiment of the present disclosure. FIG. 9 is a view showing a fourth embodiment of an arrangement relationship of active electrodes arranged in the display panel according to an embodiment of the present disclosure. FIG. 10 is a view showing a fifth embodiment of an arrangement relationship of active electrodes arranged in the display panel according to an embodiment of the present disclosure.

Referring to FIGS. 8 to 10, in describing an arrangement relationship of the active electrodes, the cover layer 30 or the like arranged on the color filter layer 20 is substantially the same as the cover layer 30 or the like described in FIGS. 1 to 7. Accordingly, the same description thereof may be omitted or provided in a simplified manner.

Referring to FIGS. 8 and 9, the display panel 100 according to an embodiment of the present disclosure may include the first active electrodes AE1 and the second active electrodes AE2 having the same shape but different sizes. For example, FIG. 8 shows the first active electrodes AE1 and the second active electrodes AE2 have a rectangular shape, and FIG. 9 shows the first active electrodes AE1 and the second active electrodes AE2 have a circular shape. However, embodiments of the present specification are not limited thereto, other shapes are possible. In this case, two second active electrodes AE2 may be arranged with the first active electrode AE1 interposed therebetween.

The first active electrodes AE1 may be patterned in a first pattern and the second active electrodes AE2 may be patterned in a second pattern. In addition, the first active electrodes AE1 and the second active electrodes AE2 may be alternately arranged along a first direction and a second direction on the plane. In this case, the first pattern and the second pattern may be formed to have the same shape but different sizes. Accordingly, since the pattern of the first reflected light formed by the first active electrode AE1 differs from the pattern of the second reflected light formed by the second active electrode AE2, the formation of a Moire may be prevented or minimized.

In addition, even when the light reflected by the color filter CF is patterned, since the first active electrodes AE1 and the second active electrodes AE2 have different sizes, the first active electrodes AE1 and the second active electrodes AE2 each may have different interference from the patterned reflected light. Accordingly, the formation of a Moire may be prevented or minimized.

In addition, one of the two second active electrodes AE2 arranged with the first active electrode AE1 interposed therebetween may be arranged to have a first distance D1 with respect to the first active electrode AE1, and the other of the two second active electrodes AE2 may be arranged to have a second distance D2 with respect to the first active electrode AE1. In this case, the first distance D1 may be smaller than the second distance D2. Here, the first distance D1 may be the shortest distance between the first active electrode AE1 and the second active electrode AE2.

Therefore, since the two second active electrodes AE2 arranged with the first active electrode AE1 interposed therebetween may be arranged to have different distances, the formation of a Moire caused by reflected light may be prevented or minimized. For example, a first reflection pattern may be formed by the reflected light formed by the first active electrodes AE1 and the second active electrodes AE2, which are arranged to be spaced the first distance D1 apart from each other. In addition, a second reflection pattern may be formed by reflected light formed by the first active electrodes AE1 and the second active electrodes AE2, which are arranged to be spaced the first distance D2 apart from each other. In this case, the first distance D1 and the second distance D2 differ from each other, and the first distance D1 and the second distance D2 may represent distances that the second active electrodes AE2 that are arranged adjacent to each other with respect to the first active electrode AE1. Accordingly, the first reflection pattern and the second reflection pattern may be configured to have different shapes, and thus, the formation of a Moire may be further prevented or minimized.

Referring to FIGS. 8 to 10, a comparison between the active electrodes AE according to the third and fourth embodiments with the active electrodes AE according to the fifth embodiment reveals a difference in that the active electrodes AE according to the fifth embodiment include the first active electrode AE1 and the second active electrode AE2 having different shapes.

Referring to FIG. 10, the active electrodes AE may include the first active electrode AE1 in a circular shape and the second active electrode AE2 in a rectangular shape. In some embodiments, the active electrodes AE may include the first active electrode AE1 in a rectangular shape and the second active electrode AE2 in a circular shape. However, embodiments of the present specification are not limited thereto. In addition, the two second active electrodes AE2 arranged with the first active electrode AE1 interposed therebetween may be arranged to have different distances with respect to the first active electrode AE1.

The first active electrode AE1 may be patterned in a circular first pattern and the second active electrode AE2 may be patterned in a rectangular second pattern. In addition, the first active electrodes AE1 and the second active electrodes AE2 may be alternately arranged along a first direction and a second direction on the plane. In this case, the first pattern and the second pattern may be formed to have different shapes and sizes. Accordingly, the pattern of the first reflected light formed by the first active electrodes AE1 and the pattern of the second reflected light formed by the second active electrodes AE2 become more different, and thus, the formation of a Moire may be further prevented or minimized.

The display device according to one or more embodiments of the present specification may be described as follows.

A display device according to one or more embodiments of the present specification may include: a display panel and an optical device arranged in the display panel, wherein the display panel includes: a substrate: a circuit layer arranged on the substrate; a light-emitting element layer arranged on the circuit layer; an encapsulation layer arranged on the light-emitting element layer; a color filter layer arranged on the encapsulation layer; and a cover layer arranged on the color filter layer, wherein the cover layer may include a first surface, which is in contact with the color filter layer, and a second surface, which is a surface opposite to the first surface, and the roughness of the second surface may be changed by power applied to the cover layer.

According to one or more embodiments of the present specification, the cover layer may include: a plurality of first active electrodes arranged to be spaced apart from each other on the color filter layer: a plurality of second active electrodes arranged to be spaced apart from the first active electrodes: and an electroactive layer configured to cover the first active electrodes and the second active electrodes. The second surface may be a top surface of the electroactive layer.

According to one or more embodiments of the present specification, the second surface may be exposed to the outside.

According to one or more embodiments of the present specification, the first active electrodes and the second active electrodes may be formed in a bar shape having a width in a first direction smaller than a length in a second direction, and the first active electrodes and the second active electrodes may be alternately arranged along the first direction.

According to one or more embodiments of the present specification, the cover layer may include a first part and a second part, which are electrically separated, and the first part and the second part each may include the plurality of first active electrodes and the plurality of second active electrode.

According to one or more embodiments of the present specification, the first active electrodes may be patterned in a first pattern, the second active electrodes may be patterned in a second pattern, and the first active electrodes and the second active electrodes may be alternately arranged along a first direction and a second direction.

According to one or more embodiments of the present specification, the display device may further include a touch sensor layer arranged between the encapsulation layer and the color filter layer, where a touch sensor metal of the touch sensor layer overlaps a black matrix of the color filter layer.

A display device according to one or more embodiments of the present specification may include: a display panel and an optical device arranged in the display panel, wherein the display panel includes: a substrate: a circuit layer arranged on the substrate; a light-emitting element layer arranged on the circuit layer; an encapsulation layer arranged on the light-emitting element layer; a color filter layer arranged on the encapsulation layer; and a cover layer arranged on the color filter layer, wherein the cover layer may include: a plurality of first active electrodes arranged to be spaced apart from each other on the color filter layer: a plurality of second active electrodes arranged to be spaced apart from the first active electrodes: and an electroactive layer configured to cover the first active electrodes and the second active electrodes.

According to one or more embodiments of the present specification, the color filter layer may include: a black matrix: a color filter arranged in an opening of the black matrix: and an insulating layer configured to cover the black matrix and the color filter.

According to one or more embodiments of the present specification, the first active electrodes and the second active electrodes may overlap the black matrix of the color filter layer.

According to one or more embodiments of the present specification, the first active electrodes and the second active electrodes may be formed in a bar shape having a width in a first direction smaller than a length in a second direction, and the first active electrodes and the second active electrodes may be alternately arranged along the first direction.

According to one or more embodiments of the present specification, the cover layer may include a first part and a second part, which are electrically separated, and the first part and the second part each may include the plurality of first active electrodes and the plurality of second active electrodes.

According to one or more embodiments of the present specification, the optical device may be an illuminance sensor, and power may be applied to at least one of the first part or the second part, based on a signal output from the illuminance sensor.

According to one or more embodiments of the present specification, the first active electrodes may be patterned in a first pattern, the second active electrodes may be patterned in a second pattern, and the first active electrodes and the second active electrodes may be alternately arranged along a first direction and a second direction.

According to one or more embodiments of the present specification, the first pattern and the second pattern may have the same shape and different sizes.

According to one or more embodiments of the present specification, one of two second active electrodes arranged with one first active electrode interposed therebetween may be arranged to have a first distance with respect to the one first active electrode, and the other of the two second active electrodes may be arranged to have a second distance with respect to the one first active electrode. The first distance may be smaller than the second distance.

According to one or more embodiments of the present specification, the first pattern and the second pattern may have different shapes and sizes.

According to one or more embodiments of the present specification, one of two second active electrodes arranged with one first active electrode interposed therebetween may be arranged to have a first distance with respect to the one first active electrode, and the other of the two second active electrodes may be arranged to have a second distance with respect to the one first active electrode. The first distance may be smaller than the second distance.

According to one or more embodiments of the present specification, power may be applied to the first active electrodes and the second active electrodes based on a signal output from the optical device provided as an illuminance sensor.

According to one or more embodiments of the present specification, the display device may further include a touch sensor layer arranged between the encapsulation layer and the color filter layer, wherein a touch sensor metal of the touch sensor layer may overlap a black matrix of the color filter layer.

According to one or more embodiments of the present specification, the first active electrodes and the second active electrodes may be formed of a transparent conductive material.

According to one or more embodiments of the present specification, when an intensity of external light is lower than a preset intensity, the electroactive layer may be deactivated.

According to one or more embodiments of the present specification, when an intensity of external light is equal to or higher than a preset intensity, the electroactive layer may be activated.

According to one or more embodiments of the present specification, a roughness of a top surface of the activated electroactive layer may be greater than a roughness of a top surface of the deactivated electroactive layer.

According to one or more embodiments of the present specification, the first part may be arranged at arranged at an upper portion of the second part, and the illuminance sensor may include an illuminance sensor arranged adjacent to the first part, and an illuminance sensor arranged adjacent to the second part.

According to one or more embodiments of the present specification, power may be only applied to the first part, based on a signal output from the illuminance sensor arranged adjacent to the first part, and power may be only applied to the second part, based on a signal output from the illuminance sensor arranged adjacent to the second part.

The objects to be achieved by the present disclosure, the means for achieving the objects, and effects of the present disclosure described above do not specify essential features of the claims, and thus, the scope of the claims is not limited to the disclosure of the present disclosure.

Although the embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a display panel and an optical device arranged in the display panel,
wherein the display panel comprises:
a substrate:
a circuit layer arranged on the substrate;
a light-emitting element layer arranged on the circuit layer;
an encapsulation layer arranged on the light-emitting element layer;
a color filter layer arranged on the encapsulation layer; and
a cover layer arranged on the color filter layer,
wherein the cover layer comprises a first surface, which is in contact with the color filter layer, and a second surface opposite to the first surface, and
a roughness of the second surface is changed by power applied to the cover layer.

2. The display device of claim 1, wherein:
the cover layer comprises: a plurality of first active electrodes spaced apart from each other on the color filter layer; a plurality of second active electrodes spaced apart from the first active electrodes; and an electroactive layer covering the first active electrodes and the second active electrodes, and
the second surface is a top surface of the electroactive layer.

3. The display device of claim 1, wherein the second surface is exposed to the outside.

4. The display device of claim 2, wherein:
the first active electrodes and the second active electrodes are formed in a bar shape having a width in a first direction smaller than a length in a second direction, and
the first active electrodes and the second active electrodes are alternately arranged along the first direction.

5. The display device of claim 2, wherein:
the cover layer comprises a first part and a second part, which are electrically separated, and
the first part and the second part each comprises the plurality of first active electrodes and the plurality of second active electrodes.

6. The display device of claim 2, wherein:
the first active electrodes are patterned in a first pattern,
the second active electrodes are patterned in a second pattern, and
the first active electrodes and the second active electrodes are alternately arranged along the first direction and the second direction.

7. The display device of claim 2, further comprising
a touch sensor layer arranged between the encapsulation layer and the color filter layer, wherein
a touch sensor metal of the touch sensor layer overlaps a black matrix of the color filter layer.

8. A display device comprising:
a display panel and an optical device arranged in the display panel,
wherein the display panel comprises:
a substrate:
a circuit layer arranged on the substrate;
a light-emitting element layer arranged on the circuit layer;
an encapsulation layer arranged on the light-emitting element layer;
a color filter layer arranged on the encapsulation layer; and
a cover layer arranged on the color filter layer,
wherein:
the cover layer comprises: a plurality of first active electrodes spaced apart from each other on the color filter layer; a plurality of second active electrodes spaced apart from the first active electrodes; and an electroactive layer configured to cover the first active electrodes and the second active electrodes.

9. The display device of claim 8, wherein the color filter layer comprises: a black matrix: a color filter arranged in an opening of the black matrix; and an insulating layer covering the black matrix and the color filter.

10. The display device of claim 9, wherein the first active electrodes and the second active electrodes overlap the black matrix of the color filter layer.

11. The display device of claim 8, wherein:
the first active electrodes and the second active electrodes are formed in a bar shape having a width in a first direction smaller than a length in a second direction, and
the first active electrodes and the second active electrodes are alternately arranged along the first direction.

12. The display device of claim 8, wherein:
the cover layer comprises a first part and a second part, which are electrically separated, and
the first part and the second part each comprises the plurality of first active electrodes and the plurality of second active electrodes.

13. The display device of claim 12, wherein:
the optical device is an illuminance sensor, and
power is applied to at least one of the first part or the second part, based on a signal output from the illuminance sensor.

14. The display device of claim 8, wherein:
the first active electrodes are patterned in a first pattern,
the second active electrodes are patterned in a second pattern, and
the first active electrodes and the second active electrodes are alternately arranged along a first direction and a second direction.

15. The display device of claim 14, wherein the first pattern and the second pattern have a same shape and different sizes.

16. The display device of claim 15, wherein:
one of two second active electrodes arranged with one first active electrode interposed therebetween is arranged to have a first distance with respect to the one first active electrode,
the other of the two second active electrodes is arranged to have a second distance with respect to the one first active electrode, and
the first distance is smaller than the second distance.

17. The display device of claim 14, wherein the first pattern and the second pattern have different shapes and sizes.

18. The display device of claim 17, wherein:
one of two second active electrodes arranged with one first active electrode interposed therebetween has a first distance with respect to the one first active electrode,
the other of the two second active electrodes has a second distance with respect to the one first active electrode, and
the first distance is smaller than the second distance.

19. The display device of claim 8, wherein power is applied to the first active electrodes and the second active electrodes based on a signal output from the optical device provided as an illuminance sensor.

20. The display device of claim 8, further comprising
a touch sensor layer arranged between the encapsulation layer and the color filter layer, wherein
a touch sensor metal of the touch sensor layer overlaps a black matrix of the color filter layer.
